(19) United States
(12) Patent Application Publication
(10) Pub. No.: US 2026/0302594 A1
(43) Pub. Date: Oct. 1, 2026

(54) SEMICONDUCTOR PACKAGE INCLUDING ANTENNA SUBSTRATE AND MANUFACTURING METHOD THEREOF

(71) Applicant: Advanced Semiconductor Engineering, Inc., Kaohsiung (TW)

(72) Inventor: Han-Chee YEN, Taipei City (TW)

(73) Assignee: Advanced Semiconductor Engineering, Inc., Kaohsiung (TW)

(21) Appl. No.: 19/688,436

(22) Filed: May 26, 2026

Related U.S. Application Data
(63) Continuation of application No. 18/203,632, filed on May 30, 2023, now Pat. No. 12,640,460.
Application No. 18/203,632 is a continuation of application No. 15/826,543, filed on Nov. 29, 2017, now Pat. No. 11,664,580.
Application No. 15/826,543 is a continuation of application No. 13/783,840, filed on Mar. 4, 2013, now Pat. No. 9,837,701.

(51) Int. Cl. H01Q 1/22; H01Q 9/04; H10W 44/20; H10W 72/00; H10W 72/29; H10W 72/59; H10W 72/90; H10W 74/00; H10W 74/01; H10W 74/10; H10W 90/00

(52) U.S. Cl. CPC H01Q 1/2283; H01Q 9/0407; H10W 44/20; H10W 74/117; H10W 90/00; H10W 44/248; H10W 72/0198; H10W 72/29; H10W 72/59; H10W 72/877; H10W 72/879; H10W 72/90; H10W 74/00; H10W 74/014; H10W 90/722; H10W 90/724; H10W 90/754

(57) ABSTRACT

A semiconductor package includes: (1) a package substrate including an upper surface; (2) a semiconductor device disposed adjacent to the upper surface of the package substrate, the semiconductor device including an inactive surface; and (3) an antenna substrate disposed on the inactive surface of the semiconductor device.

### CROSS-REFERENCE TO RELATED APPLICATION

The present application is a continuation of and claims priority to U.S. patent application Ser. No. 18/203,632, filed on May 30, 2023, which is a continuation of and claims priority to U.S. patent application Ser. No. 15/826,543, filed on Nov. 29, 2017, now U.S. Pat. No. 11,664,580, which is a continuation of and claims priority to U.S. application Ser. No. 13/783,840, filed on Mar. 4, 2013, now U.S. Pat. No. 9,837,701, the contents of which are incorporated by reference herein in their entireties.

### BACKGROUND

### Technical Field

The present embodiments relate in general to a semiconductor package and a manufacturing method thereof, and more particularly to a semiconductor package with an antenna substrate and a manufacturing method thereof.

### Description of the Related Art

Wireless communication devices, such as cell phones, typically include antennas for transmitting and receiving radio frequency (RF) signals. Conventionally, a wireless communication device includes an antenna layer and a communication module, wherein the antenna layer and the communication module are integrated together into a chip. However, when one portion of the chip, either the antenna portion or the communication module portion, is determined to be defective, the whole chip has to be discarded even if the other portion is working properly.

### SUMMARY

According to one aspect of this disclosure, a semiconductor package is provided. According to one embodiment, the semiconductor package includes: (1) a package substrate including an upper surface; (2) a semiconductor device disposed adjacent to the upper surface of the package substrate, the semiconductor device including an inactive surface; and (3) an antenna substrate disposed on the inactive surface of the semiconductor device.

According to another embodiment, the semiconductor package includes: (1) a package substrate including an upper surface; (2) a chip disposed adjacent to the upper surface of the package substrate; (3) a plurality of wires electrically connecting the chip with the package substrate; (4) an antenna substrate disposed on the chip; and (5) a spacer substrate disposed on the chip and between the antenna substrate and the package substrate to provide a space to accommodate the wires.

According to another embodiment, the semiconductor package includes: (1) a package substrate including an upper surface; (2) a semiconductor device disposed adjacent to the upper surface of the package substrate; (3) a passive component disposed adjacent to the upper surface of the package substrate; and (4) an antenna substrate disposed on the semiconductor device, the antenna substrate including a grounding layer covering the passive component.

### BRIEF DESCRIPTION OF THE DRAWINGS

FIG. 1A and FIG. 1C illustrate a cross-sectional view of an example semiconductor package according to one embodiment;

FIG. 1B illustrates a bottom view of an example antenna substrate;

FIG. 2A illustrates a cross-sectional view of an example semiconductor package according to another embodiment;

FIG. 2B illustrates a bottom view of another example antenna substrate;

FIG. 3A and FIG. 3B illustrate a cross-sectional view of an example semiconductor package according to another embodiment;

FIG. 4 illustrates a cross-sectional view of an example semiconductor package according to another embodiment;

FIG. 5A, FIG. 5B, FIG. 5C, FIG. 5D, and FIG. 5E illustrate an example manufacturing process;

FIG. 6A, FIG. 6B, FIG. 6C, FIG. 6D, and FIG. 6E illustrate an example manufacturing process.

Common reference numerals are used throughout the drawings and the detailed description to indicate similar elements. Embodiments of this disclosure will be more apparent from the following detailed description taken in conjunction with the accompanying drawings.

### DETAILED DESCRIPTION

It is desirable to have the benefits of an integrated semiconductor package including an antenna portion and a communication module portion of a wireless communication device without having reduced yield resulting from their integration. Embodiments disclosed herein provide such an integrated semiconductor package.

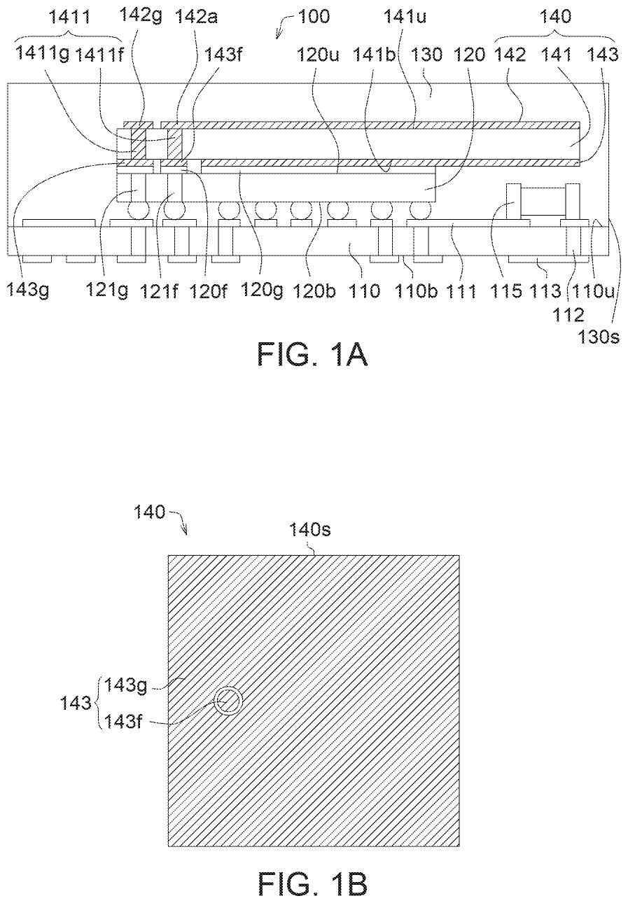

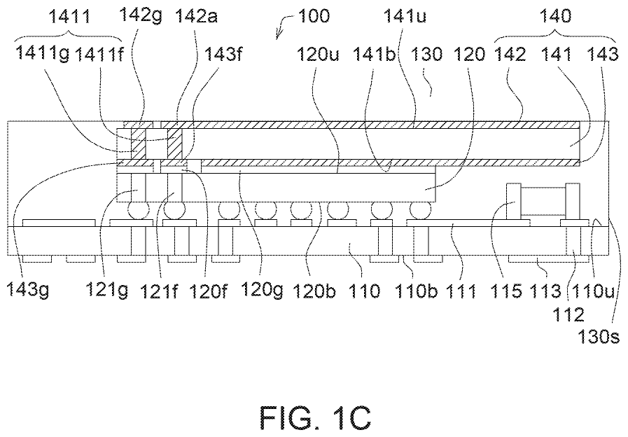

Referring to FIG. 1A, a cross-sectional view of a semiconductor package according to one embodiment is illustrated. The semiconductor package 100 includes a package substrate 110, a passive component 115, a chip 120, a package body 130 and an antenna substrate 140.

The package substrate 110 has an upper surface 110u, a lower surface 110b opposite the upper surface 110u, a trace 111, a conductive via 112 and a plurality of pads 113. The trace 111 is formed on the upper surface 110u, the conductive via 112 is extended to the lower surface 110b from the upper surface 110u, and the pads 113 are formed on the lower surface 110b. The passive component 115 and the chip 120 may be electrically connected to the pads 113 through the conductive via 112. In addition, the package substrate 110 can be a multi-layered organic substrate or a ceramic substrate, for example.

The passive component 115 is disposed on the upper surface 110u of the package substrate 110 and electrically connected to the chip 120 through the trace 111. The passive component 115 may be, for example, a resistor, an inductor or a capacitor.

The chip 120 is disposed on the upper surface 110u of the package substrate 110. The chip 120 is coupled to the upper surface 110u of the package substrate 110 in a “face-down” orientation and electrically connected to the package substrate 110 via a plurality of solder balls. This configuration is sometimes referred to as “flip-chip”. The chip 120 may be an active chip or SOC (system on chip). For example, the chip 120 may be a transceiver for transmitting radio frequency (RF) signals to the antenna substrate 140 and receiving RF signals from the antenna substrate 140.

The chip 120 includes an upper surface 120u and a feeding conductive via 121f. The chip 120 is part of a semiconductor device including a feeding layer 120f, formed on the upper surface 120u of the chip 120. The feeding layer 120f is electrically connected to the package substrate 110 through the feeding conductive via 121f. The semiconductor device further includes a grounding layer 120g formed on the upper surface 120u of the chip 120. The chip 120 includes a grounding conductive via 121g electrically connecting the grounding layer 120g and the package substrate 110. That is, the grounding layer 120g formed on the upper surface 120u of the chip 120 may be electrically connected to a ground potential through the grounding conductive via 121g. The grounding conductive via 121g and the feeding conductive via 121f may be implemented as through-silicon vias (TSV), for example.

The package body 130 encapsulates a portion of the upper surface 110u of the package substrate 110, the chip 120, and the antenna substrate 140. The package body 130 may include material such as novolac-based resin, epoxy-based resin, silicone-based resin or other suitable encapsulant. The package body 130 may also include suitable fillers such as powdered silicon dioxide. The package body 130 can be formed by various packaging technologies, such as, for example, compression molding, injection molding or transfer molding.

The antenna substrate 140 is disposed on the semiconductor device. In the illustrated embodiment, the antenna substrate 140 is directly disposed on the semiconductor device without an intervening layer, thereby reducing a signal transmission path and controlling electromagnetic interference (EMI). It is also contemplated that similar benefits can be attained by controlling a spacing between the antenna substrate 140 and the semiconductor device, such as to within about 500 μm, within about 400 μm, within about 300 μm, within about 200 μm, within about 100 μm, or with about 50 μm.

The antenna substrate 140 includes a core layer 141, an antenna layer 142 and a grounding layer 143. The core layer 141 includes an upper surface 141u, a lower surface 141b opposite the upper surface 141u, and at least one conductive via 1411. As illustrated in the embodiment of FIG. 1A, the at least one conductive via 1411 includes at least a feeding conductive via 1411f and a grounding conductive via 1411g. The core layer 141 may be a silicon substrate, an organic substrate, and a ceramic substrate, for example. The antenna layer 142 and the grounding layer 143 are respectively formed on the upper surface 141u and lower surface 141b of the core layer 141.

The grounding layer 143 includes a feeding portion 143f and a grounding portion 143g spaced and electrically isolated from the feeding portion 143f. The feeding portion 143f directly contacts the feeding layer 120f, and the feeding portion 143f is electrically connected to the feeding conductive via 121f. The grounding portion 143g directly contacts the grounding layer 120g, and the grounding portion 143g is electrically connected to the ground potential through the grounding conductive via 121g.

The grounding layer 143 can serve as a shielding layer to protect electronic components below the grounding layer 143 from EMI caused by the antenna layer 142, since the grounding portion 143g of the grounding layer 143 is electrically connected to the ground potential. For example, in the embodiment of FIG. 1A, the grounding layer 143 of the antenna substrate 140 extends over the chip 120 and over the passive component 115 to protect the chip 120 and the passive component 115 from EMI. In another embodiment, the antenna substrate 140 may extend to a lateral surface of the package body 130, such as to lateral surface 130s, to overlap the whole upper surface 110u of the package substrate 110.

The antenna layer 142 is a patterned metal layer formed on the upper surface 141u of the core layer 141. The antenna layer 142 includes a grounding portion 142g and an antenna portion 142a spaced and electrically isolated from the grounding portion 142g. The antenna portion 142a is electrically connected to the feeding portion 143f of the grounding layer 143 through the feeding conductive via 1411f, and the grounding portion 142g is electrically connected to the grounding portion 143g of the grounding layer 143 through the grounding conductive via 1411g.

The antenna substrate 140 converts electric power into radio waves, and vice versa. In transmission, the chip 120 functioning as a radio transmitter supplies an oscillating radio frequency electric current to the antenna layer 142 through the feeding conductive via 121f, the feeding layer 120f, the feeding portion 143f, and the feeding conductive via 1411f, and the antenna layer 142 radiates the energy from the current as electromagnetic waves. In reception, the antenna layer 142 intercepts the power of electromagnetic waves to produce a voltage applied to the chip 120 functioning as a radio receiver, through the feeding conductive via 1411f, the feeding portion 143f, the feeding layer 120f and the feeding conductive via 121f. The RF signal path is reduced by directly coupling the feeding conductive via 1411f of the antenna substrate 140 to the feeding conductive via 121f of the chip 120, and the RF signal attenuation is accordingly reduced.

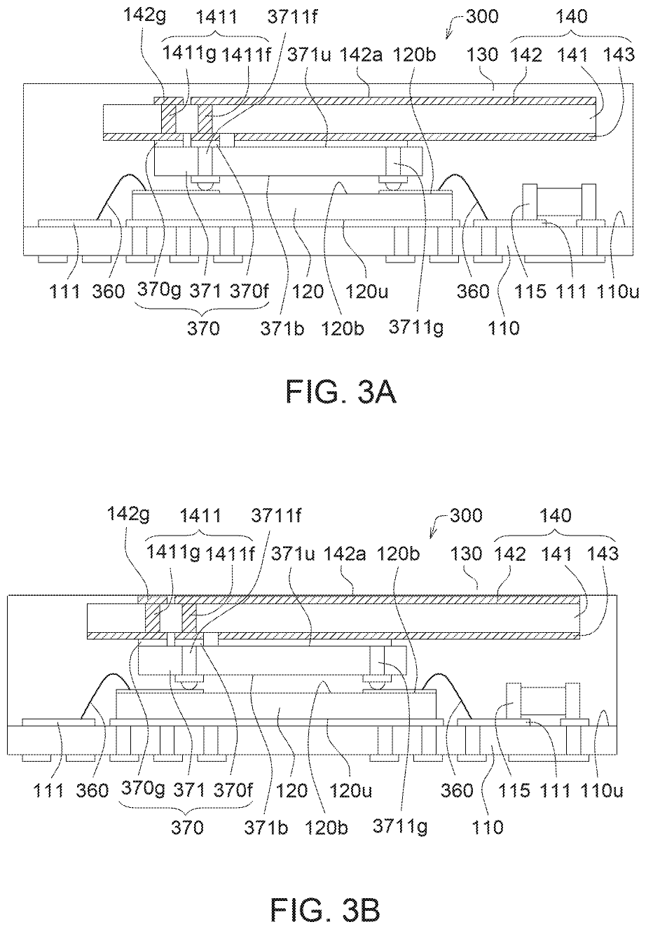

As illustrated in FIG. 1A, the antenna layer 142 is encapsulated by the package body 130. However, in another embodiment, the antenna layer 142 may be exposed from the package body 130, as shown in FIG. 1C and FIG. 3B for another embodiment. In addition, the antenna substrate 140, which passes the quality test and is a known good antenna substrate (i.e., a working antenna substrate), is disposed on the chip 120 to form the semiconductor package 100. As a result, a defective antenna substrate can be found before being disposed on the chip 120, thus yield is improved and cost is reduced.

Referring to FIG. 1B, a bottom view of the antenna substrate 140 of FIG. 1A is illustrated. The grounding portion 143g, which is spaced and electrically isolated from the feeding portion 143f, surrounds the feeding portion 143f. Moreover, the grounding portion 143g is extended to a lateral surface 140s of the antenna substrate 140 to obtain the broadest shielding area.

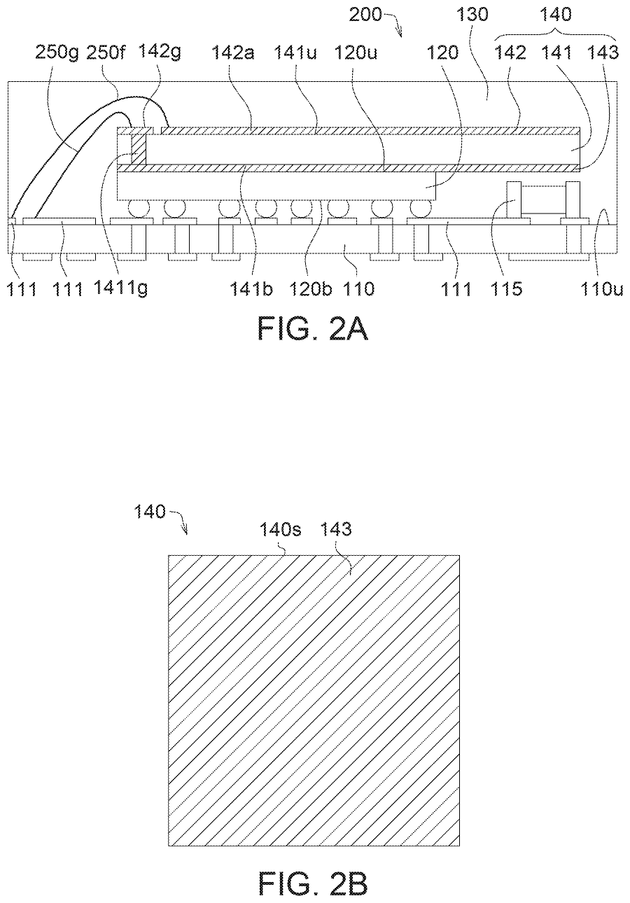

Referring to FIG. 2A, a cross-sectional view of a semiconductor package 200 according to another embodiment is illustrated. The semiconductor package 200 includes the package substrate 110, the passive component 115, the chip 120, the package body 130, the antenna substrate 140, a grounding wire 250g and a feeding wire 250f.

The chip 120 is disposed on the upper surface 110u of the package substrate 110. The chip 120 includes the upper surface 120u, and an active surface 120b opposite to the upper surface 120u. The upper surface 120u facing toward the antenna substrate 140 is an inactive surface. The active surface 120b faces toward the package substrate 110 and is electrically connected to the package substrate 110 via a plurality of solder balls.

The package body 130 encapsulates the chip 120, the antenna substrate 140 and the grounding wire 250g and the feeding wire 250f.

The antenna substrate 140 is directly disposed on the chip 120 and includes the core layer 141, the antenna layer 142 and the grounding layer 143. The core layer 141 includes the upper surface 141u, the lower surface 141b opposite to the upper surface 141u and the grounding conductive via 1411g. The antenna layer 142 is formed on the upper surface 141u of the core layer 141, and the grounding layer 143 is formed on the lower surface 141b of the core layer 141 and directly contacts the upper surface 120u of the chip 120.

The antenna layer 142 of the antenna substrate 140 includes the grounding portion 142g and the antenna portion 142a, wherein the grounding portion 142g is electrically connected to the package substrate 110 through the grounding wire 250g, and the antenna portion 142a is electrically connected to the package substrate 110 through the feeding wire 250f. The grounding layer 143 is electrically connected to the grounding portion 142g of the antenna layer 142 through the grounding conductive via 1411g. Accordingly, the grounding layer 143 is electrically connected to the ground potential through the grounding conductive via 1411g, the grounding portion 142g and the grounding wire 250g. Through a trace 111 of the package substrate 110 and the feeding wire 250f, an RF signal is transmitted from the antenna substrate 140 to the chip 120.

Referring to FIG. 2B, a bottom view of the antenna substrate of FIG. 2A is illustrated. The grounding layer 143 covers the entire lower surface 141b (illustrated in FIG. 2A) of the core layer 141, that is, the grounding layer 143 is a continuous metal layer without any hollow pattern. The bottom view shown is intended to be an example and not limiting. In another embodiment, the grounding layer 143 can be a patterned grounding layer, or can cover at least about 70%, at least about 80%, at least about 90%, or at least about 95% of the lower surface 141 b. In addition, the grounding layer 143 may be extended to at least one of the lateral surfaces 140s of the antenna substrate 140 to obtain the broadest shielding area.

Referring to FIG. 3A, a cross-sectional view of a semiconductor package 300 according to another embodiment is illustrated. The semiconductor package 300 includes the package substrate 110, the passive component 115, the chip 120, the package body 130, the antenna substrate 140, at least one conductive bond wire 360 and a spacer substrate 370.

The chip 120 may be coupled to the package substrate 110 in a “face-up” orientation, and electrically connected to the package substrate 110 via a plurality of conductive bond wires 360. The chip 120 includes the lower surface 120u facing toward the package substrate 110 and the active surface 120b facing toward the spacer substrate 370.

The antenna substrate 140 includes the core layer 141, the antenna layer 142 and the grounding layer 143. In the present embodiment, the structure of the grounding layer 143 is similar to that illustrated in FIG. 1, and the similarities are not repeated here.

The spacer substrate 370 is an interposer substrate disposed between the chip 120 and the antenna substrate 140 to provide a space to accommodate the conductive bond wires 360, thus avoiding electrical connection of the conductive bond wires 360 to the grounding layer 143 of the antenna substrate 140. In the illustrated embodiment, the antenna substrate 140 is directly disposed on the spacer substrate 370, and the spacer substrate 370 is directly disposed on the chip 120, thereby reducing a signal transmission path and controlling EMI. It is also contemplated that similar benefits can be obtained by controlling a spacing between the antenna substrate 140 and the spacer substrate 370 or a spacing between the spacer substrate 370 and the chip 120, such as to within about 500 μm, within about 400 μm, within about 300 μm, within about 200 μm, within about 100 μm, or with about 50 μm.

The spacer substrate 370 is directly coupled to the chip 120 in a “face-down” orientation and electrically connected to the chip 120 via a plurality of solder balls. The spacer substrate 370 includes a base 371, a feeding layer 370f and a grounding layer 370g. The base 371 includes an upper surface 371u and a lower surface 371b, and the feeding layer 370f and the grounding layer 370g are formed on the upper surface 371u. The base 371 further includes a feeding conductive via 3711f and a grounding conductive via 3711g, wherein the feeding conductive via 3711f electrically connects the feeding layer 370f and the chip 120, and the grounding conductive via 3711g electrically connects the grounding layer 370g and the chip 120.

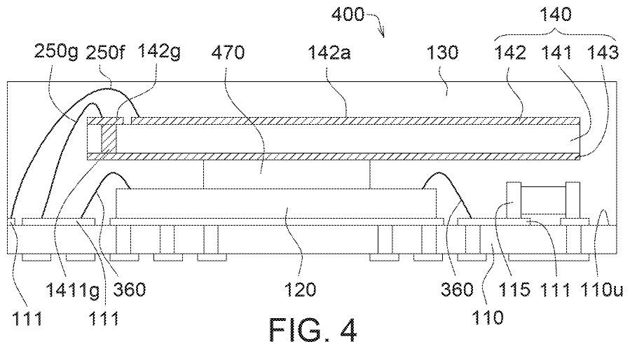

Referring to FIG. 4, a cross-sectional view of a semiconductor package 400 according to another embodiment is illustrated. The semiconductor package 400 includes the package substrate 110, the passive component 115, the chip 120, the package body 130, the antenna substrate 140, the feeding wire 250f, the grounding wire 250g, at least one conductive bond wire 360 and a spacer substrate 470.

The antenna substrate 140 includes the core layer 141, the antenna layer 142 and the grounding layer 143. In the present embodiment, the structure of the antenna substrate 140 is similar to that illustrated in FIG. 2, and the similarities are not repeated here.

The feeding wire 250f can be electrically connected to the chip 120 and the trace 111 of the package substrate 110, such that an RF signal is transmitted from the antenna substrate 140 to the chip 120 through the trace 111 of the package substrate 110 and the feeding wire 250f. The grounding portion 142g can be electrically connected to the ground potential through the grounding wire 250g and the trace 111 of the package substrate 110. Since the antenna substrate 140 can be electrically connected to the package substrate 110 through the grounding wire 250g and the feeding wire 250f, conductive elements such as vias or traces may be omitted in the spacer substrate 470.

The spacer substrate 470 is an insulation substrate, which is formed of a material including silicon or glass, for example. The spacer substrate 470 is directly disposed on the chip 120 and has an upper surface 470u. The antenna substrate 140 is directly disposed on the upper surface 470u of the spacer substrate 470.

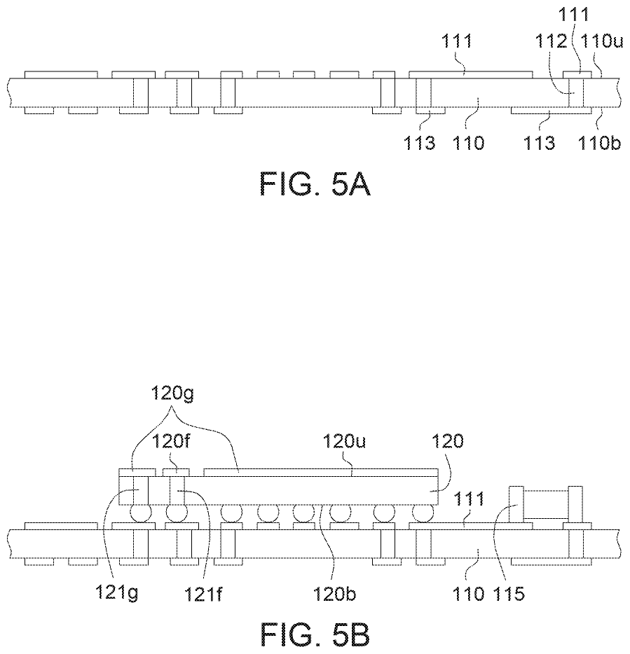

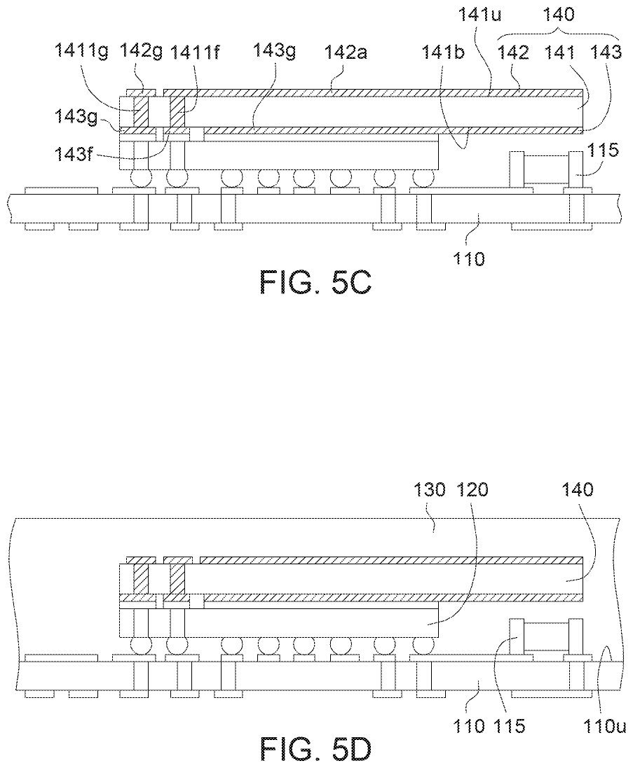

Referring to FIGS. 5A-5E, manufacturing processes according to the semiconductor package of FIG. 1A are illustrated.

Referring to FIG. 5A, the package substrate 110 is provided, wherein the package substrate 110 includes the upper surface 110u, the lower surface 110b, a plurality of the traces 111, a plurality of the conductive vias 112 and a plurality of the pads 113. The traces 111 are formed on the upper surface 110u, the conductive vias 112 extend to the lower surface 110b from the upper surface 110u, and the pads 113 are formed on the lower surface 110b. The pads 113 are electrically connected to the traces 111 through the conductive vias 112.

Referring to FIG. 5B, the passive component 115 and the chip 120 are disposed on the upper surface 110u of the package substrate 110. The chip 120 is coupled to the upper surface 110u of the package substrate 110 in a “face-down” orientation and electrically connected to the package substrate 110 via a plurality of solder balls. The chip 120 includes the upper surface 120u, and is part of a semiconductor device that includes the feeding layer 120f and the feeding conductive via 121f, wherein the feeding layer 120f is formed on the upper surface 120u of the chip 120, and the feeding conductive via 121f electrically connects the feeding layer 120f and the package substrate 110.

Referring to FIG. 5C, the antenna substrate 140 is disposed on the chip 120 using, for example, surface mount technology (SMT). The antenna substrate 140, which passes the quality test and is a known good antenna substrate (i.e., a working substrate), is disposed on the chip 120. As a result, yield is improved and cost is reduced. In the illustration, the antenna substrate 140 extends horizontally to overlap the passive component 115.

The antenna substrate 140 includes the core layer 141, the antenna layer 142 and the grounding layer 143. The core layer 141 includes the upper surface 141u, the lower surface 141b, the grounding conductive via 1411g and the feeding conductive via 1411f. The antenna layer 142 is formed on the upper surface 141u of the core layer 141, and the grounding layer 143 is formed on the lower surface 141b of the core layer 141. The antenna layer 142 includes the antenna portion 142a and the grounding portion 142g spaced and electrically isolated from the antenna portion 142a, and the grounding layer 143 includes the grounding portion 143g and the feeding portion 143f spaced and electrically isolated from the grounding portion 143g. The antenna portion 142a is electrically connected to the feeding portion 143f through the feeding conductive via 1411f, and the grounding portion 142g is electrically connected to the grounding portion 143g through grounding conductive via 1411g.

Referring to FIG. 5D, the package body 130 is formed on the upper surface 110u of the package substrate 110, encapsulating the passive element 115, the chip 120 and the antenna substrate 140.

Referring to FIG. 5E, a number of singulation paths T1 are formed passing through the package body 130 and the package substrate 110 to form the semiconductor package 100. The singulation paths T1 are formed using a laser or another cutting tool. The lateral surfaces 130s of the package body 130 and the lateral surface 110s of the package substrate 110 are formed by the singulation. The lateral surface 130s is flush with the lateral surface 110s. In the present embodiment, the singulation method is a “full-cut method”, that is, the singulation paths T1 cut fully through the package substrate 110 and the package body 130. In another embodiment, the package body 130 and the package substrate 110 can be singulated using a “half-cut method”, that is, the singulation paths T1 cut through a portion of the package substrate 110 or a portion of the package body 130.

The method of forming the semiconductor package 200 is similar to that of forming the semiconductor package 100 of FIG. 1A, and the similarities are not repeated here.

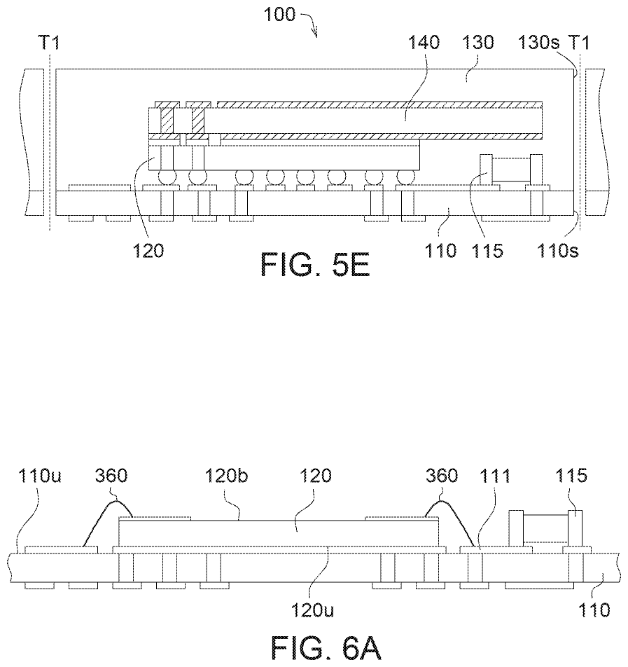

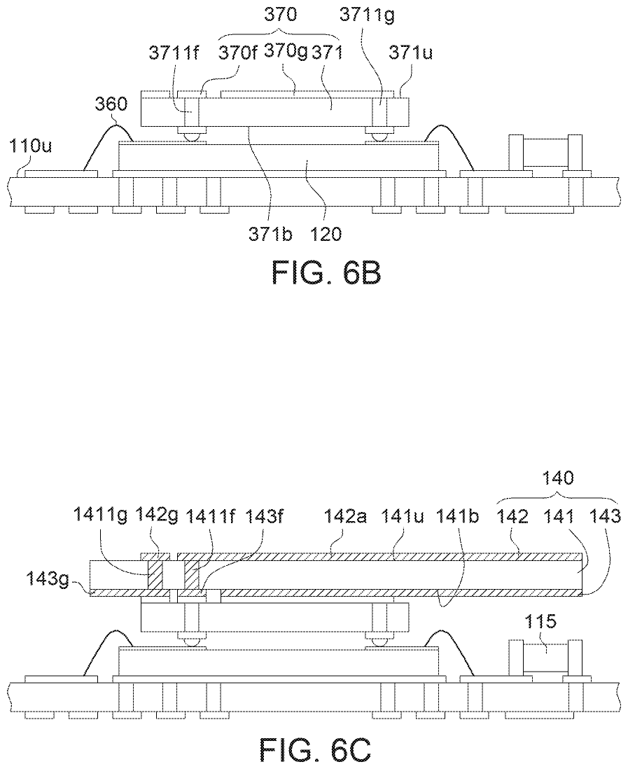

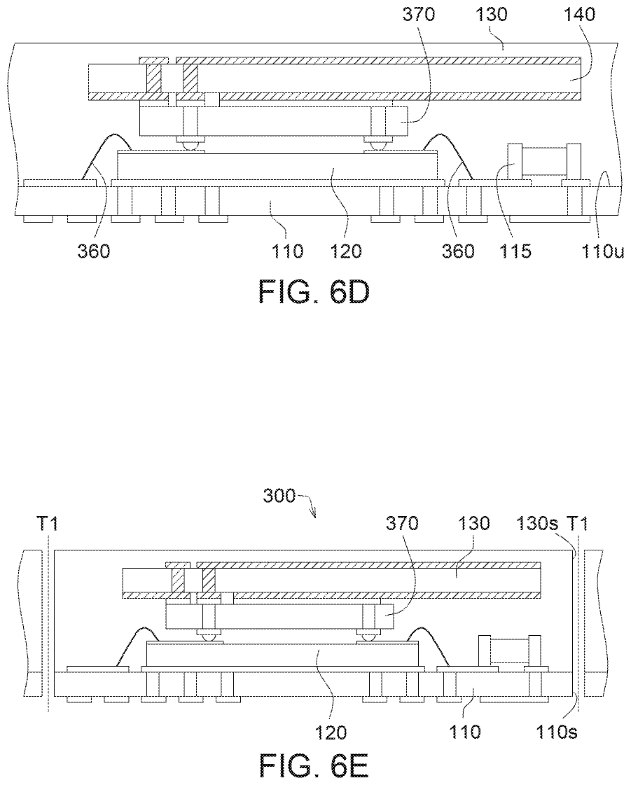

Referring to FIGS. 6A-6E, manufacturing processes according to the semiconductor package of FIG. 3 are illustrated.

Referring to FIG. 6A, the passive component 115 and the chip 120 are disposed on the upper surface 110u of the package substrate 110. The chip 120 is coupled to the upper surface 110u of the package substrate 110 in a “face-up” orientation and electrically connected to the package substrate 110 via a plurality of conductive bond wires 360.

Referring to FIG. 6B, the spacer substrate 370 is disposed on the chip 120. The spacer substrate 370 is directly coupled to the chip 120 in a “face-down” orientation and electrically connected to the chip 120 via a plurality of solder balls. The spacer substrate 370 includes the base 371, the feeding layer 370f and the grounding layer 370g. The base 371 includes the upper surface 371u and the lower surface 371b, wherein the feeding layer 370f and the grounding layer 370g are formed on the upper surface 371u. The base 371 further includes a feeding conductive via 3711f and the grounding conductive via 3711g, wherein the feeding conductive via 3711f electrically connects the feeding layer 370f and the chip 120, and the grounding conductive via 3711g electrically connects the grounding layer 370g and the chip 120.

Referring to FIG. 6C, the antenna substrate 140 is disposed on the spacer substrate 370 using, for example, SMT. The antenna substrate 140, which passes the quality test and is a known good antenna substrate (i.e., a working antenna substrate), is disposed on the spacer substrate 370. In the illustration, the antenna substrate 140 extends horizontally to overlap the passive component 115.

The antenna substrate 140 includes the core layer 141, the antenna layer 142 and the grounding layer 143, wherein the core layer 141 includes the upper surface 141u, the lower surface 141b, the grounding conductive via 1411g and the feeding conductive via 1411f. The antenna layer 142 is formed on the upper surface 141u of the core layer 141, and the grounding layer 143 is formed on the lower surface 141b of the core layer 141. The antenna layer 142 includes the antenna portion 142a and the grounding portion 142g spaced and electrically isolated from the antenna portion 142a. The grounding layer 143 includes the grounding portion 143g and the feeding portion 143f spaced and electrically isolated from the grounding portion 143g. The grounding portion 143g is electrically connected to the grounding portion 142g through the grounding conductive via 1411g, and the feeding portion 143f is electrically connected to the antenna portion 142a through the feeding conductive via 1411f.

Referring to FIG. 6D, the package body 130 is formed on the upper surface 110u of the package substrate 110, encapsulating the passive component 115, the chip 120, the antenna substrate 140 and the conductive bond wires 360.

Referring to FIG. 6E, a number of singulation paths T1 passing through the package body 130 and the package substrate 110 are formed to form the semiconductor package 300. The singulation paths T1 are formed using a laser or another cutting tool. The lateral surface 130s of the package body 130 and the lateral surface 110s of the package substrate 110 are formed, such that the lateral surface 130s is flush with the lateral surface 110s. In the present embodiment, the singulation method is a “full-cut method”, that is, the singulation paths T1 cut fully through the package substrate 110 and the package body 130.

The method of forming the semiconductor package 400 is similar to that of forming the semiconductor package 400 of FIG. 4, and the similarities are not repeated here.

While the invention has been described and illustrated with reference to specific embodiments thereof, these descriptions and illustrations do not limit the invention. It should be understood by those skilled in the art that various changes may be made and equivalents may be substituted without departing from the true spirit and scope of the invention as defined by the appended claims. The illustrations may not necessarily be drawn to scale. There may be distinctions between the artistic renditions in the present disclosure and the actual apparatus due to manufacturing processes and tolerances. There may be other embodiments of the present invention which are not specifically illustrated. The specification and the drawings are to be regarded as illustrative rather than restrictive. Modifications may be made to adapt a particular situation, material, composition of matter, method, or process to the objective, spirit and scope of the invention. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A semiconductor package comprising:
a circuit structure;
an electronic component disposed adjacent to the circuit structure;
an antenna substrate disposed adjacent to the circuit structure; and
a ground potential layer closer to the circuit structure than the antenna substrate.

2. The semiconductor package as claimed in claim 1, wherein the antenna substrate comprises a grounding layer electrically connected to the ground potential layer.

3. The semiconductor package as claimed in claim 1, further comprising an electromagnetic interference (EMI) shielding layer disposed adjacent to the electronic component.

4. The semiconductor package as claimed in claim 3, further comprising a passive component disposed adjacent to the shielding layer, wherein the EMI shielding layer is configured to shield the passive component from EMI.

5. The semiconductor package as claimed in claim 3, further comprising an encapsulant encapsulating the electronic component.

6. The semiconductor package as claimed in claim 1, further comprising a passive component adjacent to the circuit structure.

7. The semiconductor package as claimed in claim 6, wherein the electronic component is electrically connected to the passive component through a trace of the circuit structure.

8. The semiconductor package as claimed in claim 1, wherein the antenna substrate has a first side and a second side, the circuit structure has a third side adjacent to the first side and a fourth side adjacent to the second side, and a distance between the first side and the third side is greater than a distance between the second side and the fourth side.

9. The semiconductor package as claimed in claim 1, further comprising a solder disposed between the antenna substrate and the circuit structure, and electrically connecting the antenna substrate and the electronic component.

10. The semiconductor package as claimed in claim 1, wherein a thickness of the antenna substrate is greater than a thickness of the electronic component.

11. The semiconductor package as claimed in claim 1, wherein the antenna substrate comprises:
a core layer;
an antenna layer adjacent to the core layer; and
a conductive via penetrating the core layer and electrically connecting the antenna layer with the electronic component.

12. The semiconductor package as claimed in claim 11, wherein the circuit structure comprises a conductive via substantially overlapping the conductive via of the antenna substrate.

13. The semiconductor package as claimed in claim 1, further comprising a spacer disposed between the circuit structure and the antenna substrate, wherein the electronic component is electrically connected to the circuit structure through a connection element, wherein the spacer is spaced apart from the connection element by a gap.

14. A semiconductor package comprising:
a package substrate;
an antenna substrate disposed adjacent to the package substrate; and
a spacer disposed between the package substrate and the antenna substrate and configured to transmit an RF signal between the package substrate and the antenna substrate.

15. The semiconductor package as claimed in claim 14, wherein a lateral side of the antenna substrate is misaligned with a lateral side of the package substrate.

16. The semiconductor package as claimed in claim 14, wherein the spacer is configured to support the antenna substrate.

17. The semiconductor package as claimed in claim 14, further comprising a chip adjacent to the package substrate and electrically connected to the package substrate through a connection element, wherein the spacer is spaced apart from the connection element by a gap.

18. The semiconductor package as claimed in claim 17, further comprising an encapsulant encapsulating an active surface of the chip facing the antenna substrate, wherein the encapsulant at least exposes a surface of the antenna substrate.

19. The semiconductor package as claimed in claim 14, wherein a width of the antenna substrate is greater than a width of the spacer, and wherein a projection of the spacer on the package substrate is completely within a projection of the antenna substrate on the package substrate.

20. The semiconductor package as claimed in claim 14, wherein the antenna substrate comprises a conductive layer, and the conductive layer comprises a grounding portion and a feeding portion.
